(19) United States
(12) Patent Application Publication
(10) Pub. No.: US 2026/0215263 A1
(43) Pub. Date: Jul. 23, 2026

(54) SEMICONDUCTOR PACKAGE, SEMICONDUCTOR DEVICE, AND MANUFACTURING METHOD FOR SEMICONDUCTOR PACKAGE

(71) Applicant: SONY SEMICONDUCTOR SOLUTIONS CORPORATION, KANAGAWA (JP)

(72) Inventor: Tatehito KOBAYASHI, KANAGAWA (JP)

(21) Appl. No.: 19/157,946

(22) PCT Filed: Jan. 10, 2024
(86) PCT No.: PCT/JP2024/000246

§ 371 Date: Aug. 19, 2025

(30) Foreign Application Priority Data
Mar. 6, 2023 (JP) 2023-033324

(51) Int. Cl. H10W 40/28; H10F 39/00; H10F 39/18; H10W 40/00; H10W 40/20; H10W 70/00; H10W 70/05; H10W 70/68; H10W 72/50; H10W 90/00

(52) U.S. Cl. CPC H10W 40/28; H10W 40/037; H10W 40/233; H10W 40/235; H10W 70/093; H10W 70/099; H10W 70/682; H10W 72/5473; H10W 90/766; H10F 39/18; H10F 39/811

(57) ABSTRACT

To improve heat dissipation performance in a semiconductor package in which wire bonding is performed.

A semiconductor package includes a semiconductor chip, a package substrate, a Peltier element, a first wire, and a second wire. In this semiconductor package, the Peltier element cools a predetermined relay pad and the semiconductor chip. Furthermore, in the semiconductor package, the first wire connects the semiconductor chip and the relay pad. Furthermore, the second wire connects the relay pad and the package substrate.

### TECHNICAL FIELD

The present technology relates to a semiconductor package. Specifically, the present technology relates to a semiconductor package that cools a semiconductor chip, a semiconductor device, and a manufacturing method for the semiconductor package.

### BACKGROUND ART

Conventionally, in a semiconductor chip having large power consumption such as an image sensor, heat generated during operation adversely affects performance, and thus thermal management is required. For example, there has been proposed a semiconductor package having a structure in which a semiconductor chip is mounted on a Peltier module disposed in a cavity of a package substrate, and the semiconductor chip and the package substrate are connected by a wire (See, for example, Patent Document 1.).

### CITATION LIST

### Patent Document

Patent Document 1: Japanese Patent Application Laid-Open No. H7-38019

### SUMMARY OF THE INVENTION

### Problems to be Solved by the Invention

In the above-described conventional technology, the Peltier module is used to dissipate heat from the semiconductor chip to the package substrate. However, in the above-described semiconductor package, heat may return from the package substrate of a heat dissipation destination to the semiconductor chip via the wire, and there is a problem that heat dissipation performance is deteriorated due to the heat return.

The present technology has been made in view of such a situation, and an object thereof is to improve heat dissipation performance in a semiconductor package in which wire bonding is performed.

### Solutions to Problems

The present technology has been made to solve the above-described problem, and a first aspect thereof is a semiconductor package including: a semiconductor chip; a package substrate; a Peltier element that cools a predetermined relay pad and the semiconductor chip; a first wire that connects the semiconductor chip and the relay pad; and a second wire that connects the relay pad and the package substrate, and a manufacturing method for the semiconductor package. This brings about an effect of improving heat dissipation performance.

Furthermore, in the first aspect, a third wire that connects the package substrate and the semiconductor chip and transmits an electric signal may be further included, and power may be supplied to the semiconductor chip via the first wire and the second wire. This brings about an effect that the signal quality of the electric signal is maintained.

Furthermore, in the first aspect, a plurality of the first wires and one of the second wires may be connected to one of the relay pads. This brings about an effect that the number of wirings is reduced.

Furthermore, in the first aspect, a heat absorption side substrate on which the semiconductor chip is mounted and a heat dissipation side substrate bonded to the package substrate may be further included, and the Peltier element may be disposed between the heat absorption side substrate and the heat dissipation side substrate. This brings about an effect that heat moves from the heat absorption side substrate to the heat dissipation side substrate.

Furthermore, in the first aspect, the relay pad may be disposed on the heat absorption side substrate. This brings about an effect of suppressing heat return.

Furthermore, in the first aspect, a wiring board bonded to the heat absorption side substrate with an adhesive may be further included, and the relay pad may be disposed on the wiring board. This brings about an effect of suppressing heat return when the wiring board is added.

Furthermore, in the first aspect, a fourth wire that connects the heat absorption side substrate and the package substrate may be further provided, and power may be supplied to the Peltier element via the fourth wire. This brings about an effect that the Peltier element is driven.

Furthermore, in the first aspect, a fourth wire that connects the heat dissipation side substrate and the package substrate may be further provided, and power may be supplied to the Peltier element via the fourth wire. This brings about an effect of suppressing heat return via the fourth wire.

Furthermore, in the first aspect, a heat absorption side substrate on which the semiconductor chip is mounted may be further included, and the Peltier element may be disposed between the heat absorption side substrate and the package substrate. This brings about an effect of further improving heat dissipation performance.

Furthermore, a second aspect of the present technology is a semiconductor device including: a semiconductor chip; a package substrate; a Peltier element that cools a predetermined relay pad and the semiconductor chip; a first wire that connects the semiconductor chip and the relay pad; a second wire that connects the relay pad and the package substrate; and a power supply circuit that supplies power to the semiconductor chip via the first wire and the second wire. This brings about an effect of improving heat dissipation performance of the semiconductor device.

### BRIEF DESCRIPTION OF DRAWINGS

FIG. 1 is an example of a cross-sectional view and a top view illustrating a configuration example of a semiconductor package according to a first embodiment of the present technology.

FIG. 2 is an example of a cross-sectional view of another side and a top view of the semiconductor package according to the first embodiment of the present technology.

FIG. 3 is an example of a cross sectional view of another side and a top view of the semiconductor package according to the first embodiment of the present technology.

FIG. 4 is an example of a cross-sectional view of a semiconductor package in a comparative example and an enlarged view of the semiconductor package according to the first embodiment.

FIG. 5 is a diagram for describing a manufacturing method for the semiconductor package according to the first embodiment of the present technology.

FIG. 6 is a flowchart illustrating an example of the manufacturing method for the semiconductor package according to the first embodiment of the present technology.

FIG. 7 is a block diagram illustrating a configuration example of a semiconductor device of the first embodiment of the present technology.

FIG. 8 is an example of a cross-sectional view and a top view illustrating a configuration example of a semiconductor package according to a second embodiment of the present technology.

FIG. 9 is an example of a cross-sectional view of the semiconductor package according to the second embodiment of the present technology.

FIG. 10 is a diagram for describing a manufacturing method for the semiconductor package according to the second embodiment of the present technology.

FIG. 11 is an example of a cross-sectional view and a top view illustrating a configuration example of a semiconductor package according to a third embodiment of the present technology.

FIG. 12 is an example of a cross-sectional view of the semiconductor package according to the third embodiment of the present technology.

FIG. 13 is a diagram for describing a manufacturing method for the semiconductor package according to the third embodiment of the present technology.

FIG. 14 is an example of a cross-sectional view and a top view illustrating a configuration example of a semiconductor package according to a fourth embodiment of the present technology.

FIG. 15 is an example of a cross-sectional view of the semiconductor package according to the fourth embodiment of the present technology.

FIG. 16 is a block diagram illustrating a schematic configuration example of a vehicle control system.

FIG. 17 is an explanatory diagram illustrating an example of an installation position of an imaging section.

### MODE FOR CARRYING OUT THE INVENTION

Modes for carrying out the present technology (hereinafter, referred to as embodiments) will be described below. The description will be given in the following order.
1. First embodiment (Example of wiring via a pad of a Peltier module)
2. Second embodiment (Example of wiring via a pad of a wiring board)
3. Third embodiment (Example of wiring via a pad of a heat dissipation side substrate of a Peltier module)
4. Fourth embodiment (Example of reducing a heat dissipation side substrate and wiring via a pad of a Peltier module)
5. Application examples to mobile body

### 1. First Embodiment

### Configuration Example of Semiconductor Package

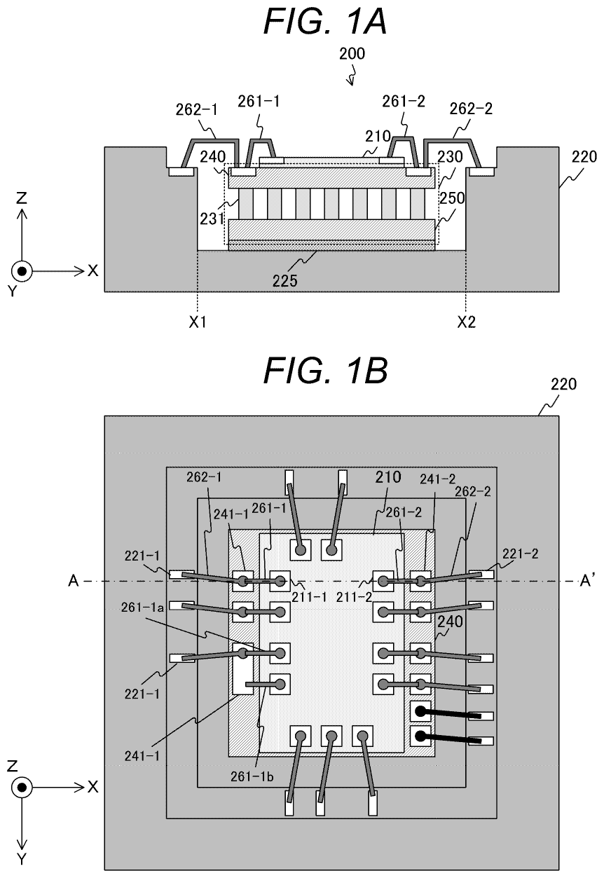

FIG. 1 is an example of a cross-sectional view and a top view of a configuration example of a semiconductor package 200 according to a first embodiment of the present technology. a in the drawing is an example of a cross-sectional view of the semiconductor package 200, and b in the drawing is an example of a top view of the semiconductor package 200.

As illustrated in a of the drawing, the semiconductor package 200 includes a semiconductor chip 210, a package substrate 220, and a Peltier module 230.

Hereinafter, a predetermined axis parallel to a chip plane of the semiconductor chip 210 is referred to as an “X axis”, and a predetermined axis perpendicular to the chip plane is referred to as a “Z axis”. An axis perpendicular to the X axis and the Z axis is set as a “Y axis”. Furthermore, a direction from the Peltier module 230 to the semiconductor chip 210 is defined as an “upper” direction.

a in the drawing is a cross-sectional view of the semiconductor package 200 cut along a line segment A-A′ of b in the drawing as viewed from the Y-axis direction.

The package substrate 220 includes a cavity. A recess in a region from a coordinate X1 to a coordinate X2 in a of the drawing corresponds to the cavity. A lower surface of the Peltier module 230 is bonded to a bottom surface of the cavity with an adhesive 225. For example, a ceramic substrate is used as the package substrate 220. Furthermore, as the adhesive 225, a die bonding material having relatively high thermal conductivity such as a silver paste or a conductive resin is used.

The Peltier module 230 includes a heat absorption side substrate 240, a heat dissipation side substrate 250, and a predetermined number of Peltier elements 231. The heat dissipation side substrate 250 is adhered to the bottom surface of the cavity, and the predetermined number of Peltier elements 231 are disposed between the heat absorption side substrate 240 and the heat dissipation side substrate 250. Furthermore, the semiconductor chip 210 is mounted on an upper surface of the heat absorption side substrate 240. For example, a CMOS image sensor (CIS) is used as the semiconductor chip 210.

When power is supplied, the Peltier element 231 transfers heat from the heat absorption side substrate 240 to the heat dissipation side substrate 250.

As illustrated in b of the drawing, a plurality of pads such as 211-1 and 211-2 is disposed on an upper surface of the semiconductor chip 210.

Furthermore, an area of an upper surface (that is, the upper surface of the heat absorption side substrate 240) of the Peltier module 230 is larger than that of the semiconductor chip 210, and a plurality of pads such as 241-1 and 241-2 is disposed along an outer periphery of the semiconductor chip 210.

Furthermore, on an upper surface of the package substrate 220, a plurality of inner leads such as 221-1 and 221-2 is disposed along the outer periphery of the cavity.

The pad 211-1 of the semiconductor chip 210 is electrically connected to the pad 241-1 of the Peltier module 230 by a wire 261-1 which is a power supply line. Furthermore, the pad 241-1 of the Peltier module 230 is electrically connected to the inner lead 221-1 of the package substrate 220 by a wire 262-1 which is a power supply line.

Furthermore, the pad 211-2 of the semiconductor chip 210 is electrically connected to the pad 241-2 of the Peltier module 230 by a wire 261-2 which is a ground line. Furthermore, the pad 241-2 of the Peltier module 230 is electrically connected to the inner lead 221-2 of the package substrate 220 by a wire 262-2 which is a ground line.

Note that the wires 261-1 and 261-2 are examples of a first wire recited in the claims, and the wires 262-1 and 262-2 are examples of a second wire recited in the claims. The pads 241-1 and 241-2 are an example of a relay pad recited in the claims.

As described above, the power supply line and the ground line for supplying power to the semiconductor chip 210 connect the semiconductor chip 210 and the package substrate 220 via the pads of the Peltier module 230.

Power is supplied to the semiconductor chip 210 via the power supply line and the ground line.

Furthermore, like wires 261-1a and 261-1b, a wire (power supply line or ground line) for supplying power may be commonly connected to one pad 241-1 and bundled, and the pad 241-1 and the inner lead 221-1 may be connected by one wire. Therefore, the number of wirings between the Peltier module 230 and the package substrate 220 can be reduced. Furthermore, since the wire connecting the package substrate 220 and the semiconductor chip 210 serves as a heat transfer path, an effect of thinning the path is produced.

Note that, although the cavity is not sealed with glass, a frame, or the like in the drawing, glass or a frame may be further added to seal the cavity. The semiconductor package 200 having an unsealed structure is used, for example, in a vacuum.

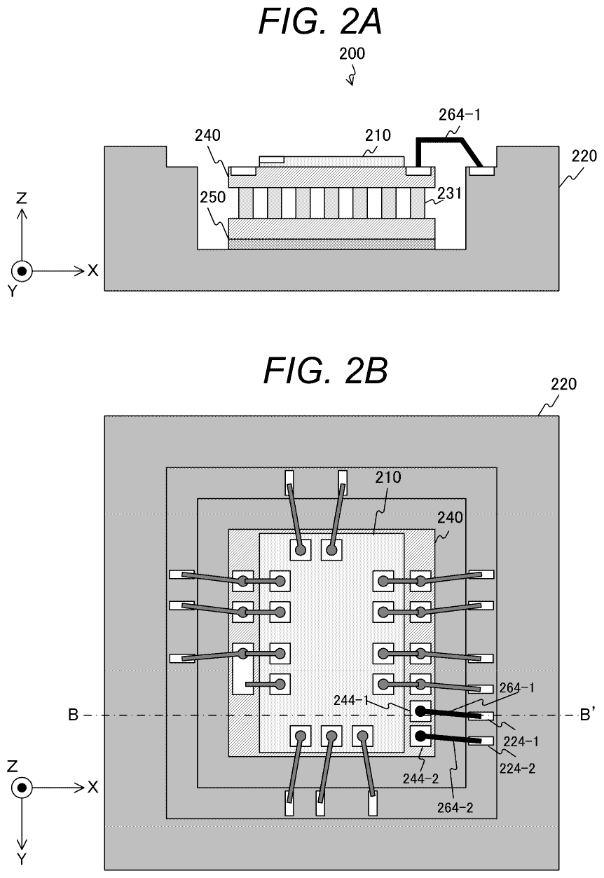

a in FIG. 2 is a cross-sectional view of the semiconductor package 200 cut along a line segment B-B′ of b in FIG. 2 as viewed from the Y-axis direction. For convenience of description, reference signs in the vicinity of the line segment A-A′ in FIG. 1 are omitted in b of FIG. 2.

As illustrated in b of FIG. 2, a plurality of pads such as 244-1 and 244-2 is disposed on the upper surface of the Peltier module 230. Furthermore, on the upper surface of the package substrate 220, a plurality of inner leads such as 224-1 and 224-2 is disposed along the outer periphery of the cavity.

Furthermore, the pad 244-1 of the Peltier module 230 is used as a + terminal, and is electrically connected to the inner lead 224-1 of the package substrate 220 by the wire 264-1. The pad 244-2 of the Peltier module 230 is used as a-terminal and is electrically connected to the inner lead 224-2 of the package substrate 220 by the wire 264-2. Power is supplied to a Peltier module 230 through these wires. Note that the wires 264-1 and 264-2 are examples of a fourth wire recited in the claims.

As described above, the wires 264-1 and 264-2 for supplying power to the Peltier module 230 directly connect the Peltier module 230 and the package substrate 220.

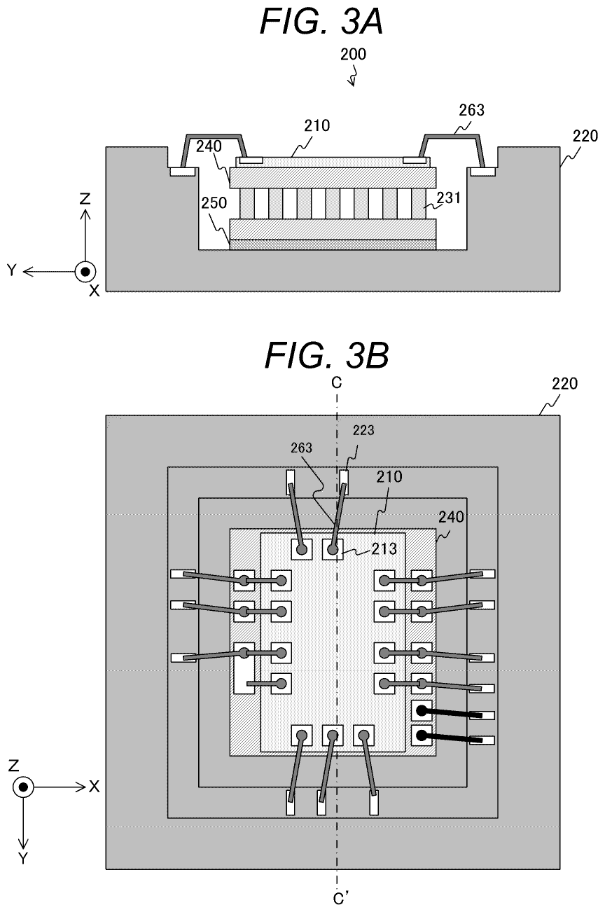

a in FIG. 3 is an example of a cross-sectional view of the semiconductor package 200 taken along a line segment C-C′ of b in FIG. 3 and viewed from the X-axis direction. For convenience of description, reference signs in the vicinity of the line segment A-A′ in b of FIG. 1 are omitted in b of FIG. 3.

As illustrated in b of FIG. 3, a plurality of pads such as 213 is disposed on the upper surface of the semiconductor chip 210. Furthermore, on the upper surface of the package substrate 220, a plurality of inner leads such as 223 is disposed along the outer periphery of the cavity.

Furthermore, the pad 213 of the semiconductor chip 210 is electrically connected to the inner lead 223 of the package substrate 220 by a wire 263 which is a signal line. Various electric signals such as a clock signal, a pixel signal, and a control signal are transmitted through the wire 263. Note that the wire 263 is an example of a third wire recited in the claims.

As described above, the semiconductor chip 210 and the package substrate 220 are directly connected by the signal line.

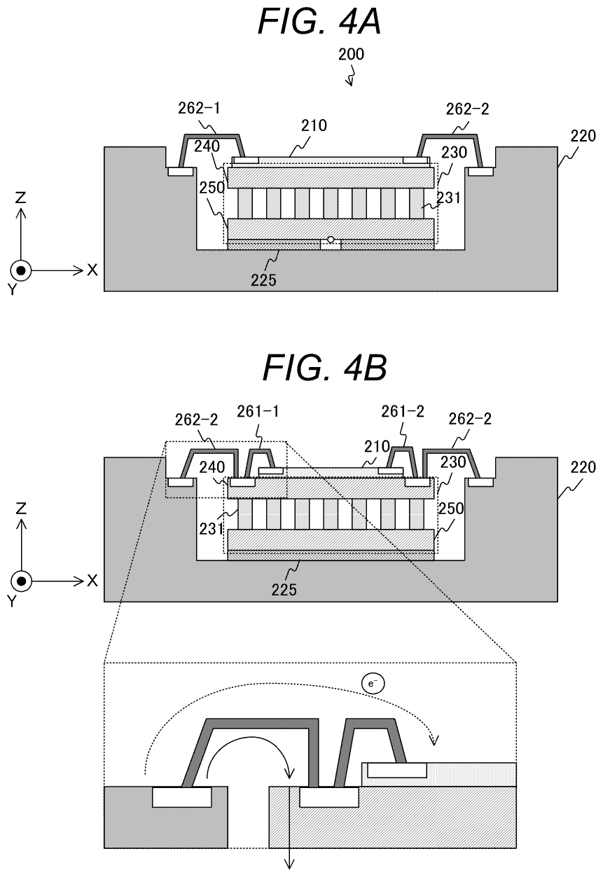

Here, as illustrated in a of FIG. 4, a comparative example of a configuration in which the power supply line and the ground line (262-1 and 262-2) of the semiconductor chip 210 directly connect the semiconductor chip 210 and the package substrate 220 without passing through the pads of the Peltier module 230 is assumed. Furthermore, in this comparative example, pads 244-1 and 244-2 for supplying power to the Peltier module 230 are not disposed on the heat absorption side substrate 240, and + and − power supply terminals (not illustrated) having the same function are disposed on the lower surface of the heat dissipation side substrate 250. It is assumed that the + and − power supply terminals are disposed on both sides of a white circle in a of the drawing. A region to which the adhesive 225 is not applied is provided between these terminals in order to prevent a short circuit.

As described above, heat is transferred from the semiconductor chip 210 to the package substrate 220 by the Peltier module 230, and the semiconductor chip 210 is cooled. However, in the comparative example, heat return, which is a phenomenon in which heat transferred to the package substrate 220 returns to the semiconductor chip 210 via the signal line, the power supply line, and the ground line, may occur. For example, it is assumed that the number of signal lines of the semiconductor chip 210 is 40, the number of power supply lines and ground lines is 200, and a temperature rise of 4° C. occurs due to the heat return through a total of 240 wires. In the comparative example, the heat dissipation performance is deteriorated by the temperature rise.

Furthermore, in the comparative example, since the + and − power supply terminals are disposed on the lower surface of the heat dissipation side substrate 250, an area of the adhesive 225 (silver paste or the like) on the lower surface is reduced by an area of a region between the terminals necessary for preventing the short circuit.

On the other hand, as illustrated in b of the drawing, in the first embodiment, the power supply line and the ground line of the semiconductor chip 210 are connected to the package substrate 220 via the pads of the Peltier module 230. As described above, once the heat passes through the pads of the Peltier module 230, the heat can be transferred to the heat dissipation side substrate 250 again before the heat returns to the semiconductor chip 210. A solid arrow in b of the drawing indicates a heat transfer path, and a dotted arrow indicates an electron transfer path.

Therefore, the heat return through the power supply line and the ground line of the semiconductor chip 210 can be suppressed. Since the heat return is for 40 signal lines, the temperature rise due to the heat return is obtained by, for example, the following formula.

$$4 ° C . \times 40 / 240 \approx 0.6 ° C .$$

In the above formula, the right side is a value obtained by rounding down a fraction after the second decimal place.

As exemplified in the above formula, by wiring the power supply line and the ground line via the pads of the Peltier module 230, an amount of temperature rise due to the heat return can be suppressed as compared with the comparative example. Therefore, heat dissipation performance can be improved. On the other hand, since the signal line is directly connected between the semiconductor chip 210 and the package substrate 220, the signal quality of the electric signal transmitted by the signal line is not deteriorated as compared with the comparative example.

Furthermore, in the first embodiment, since the pads 244-1 and 244-2 for supplying power are disposed on the heat absorption side substrate 240, it is not necessary to dispose the power supply terminals on the lower surface of the heat dissipation side substrate 250. Therefore, the area of the adhesive 225 (silver paste or the like) can be made larger than that of the comparative example.

### Manufacturing Method for Semiconductor Package

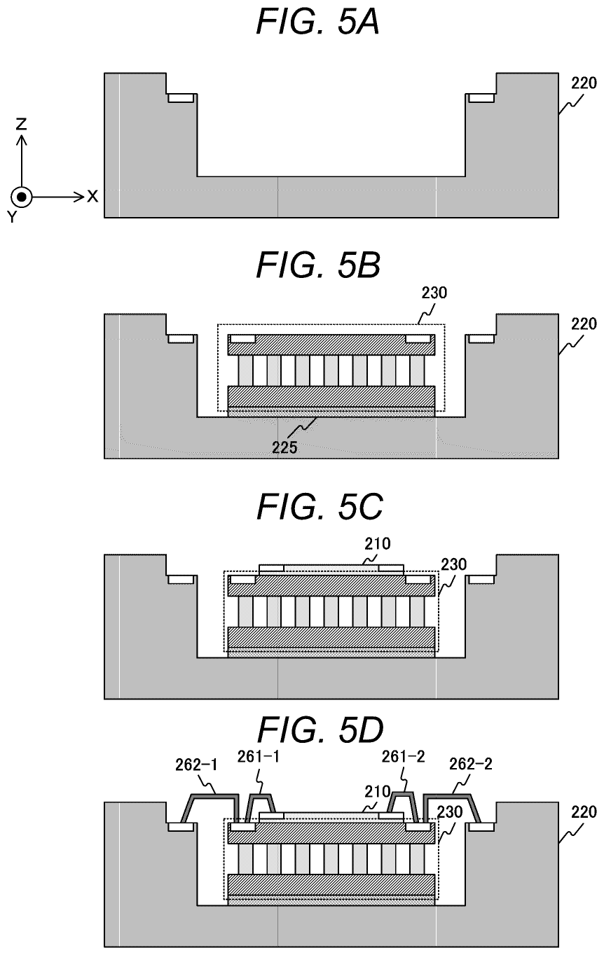

FIG. 5 is a diagram for describing a manufacturing method for the semiconductor package 200 according to the first embodiment of the present technology. First, as illustrated in a of the drawing, the package substrate 220 including the cavity is manufactured.

Next, as exemplified in b of the drawing, the Peltier module 230 is adhered to the bottom surface of the cavity with the adhesive 225 (silver paste or the like).

Then, as illustrated in c of the drawing, the semiconductor chip 210 is mounted on the upper surface of the Peltier module 230.

Subsequently, as illustrated in d in the drawing, the wire 261 connecting the semiconductor chip 210 and the Peltier module 230 and the wire 262 connecting the Peltier module 230 and the package substrate 220 are wired. The wire 261 in d of the drawing includes a wire 261-1 and a wire 261-2. The wire 262 includes a wire 262-1 and a wire 262-2.

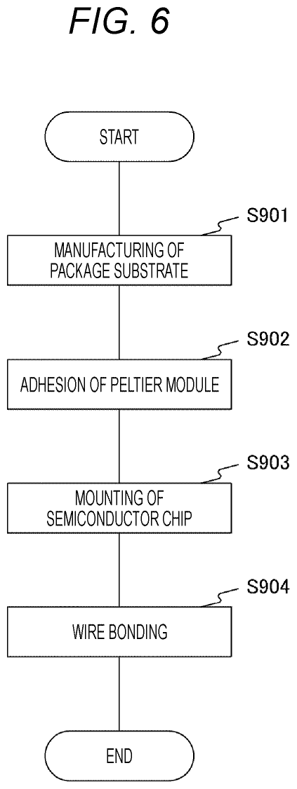

FIG. 6 is a flowchart illustrating an example of a manufacturing method for the semiconductor package according to the first embodiment of the present technology. First, the package substrate 220 including the cavity is manufactured (step S901). Next, the Peltier module 230 is bonded to the bottom surface of the cavity (step S902), and the semiconductor chip 210 is mounted on the top surface of the Peltier module 230 (step S903). Then, the semiconductor chip 210 is connected to the package substrate 220 by wire bonding (step S904). After step S904, various subsequent processes are executed as necessary, and the manufacturing process of the semiconductor package 200 is ended.

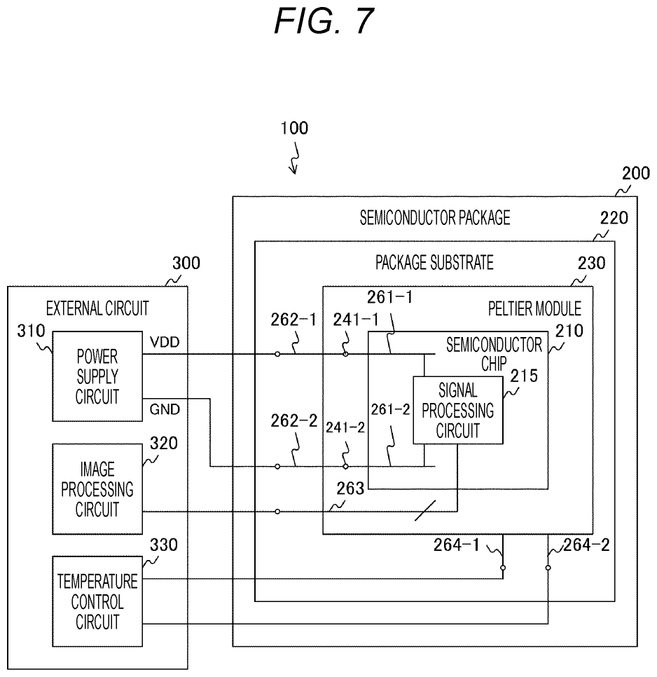

FIG. 7 is a block diagram illustrating a configuration example of a semiconductor device 100 in the first embodiment of the present technology. The semiconductor device 100 includes the above-described semiconductor package 200 and an external circuit 300. The external circuit 300 includes a power supply circuit 310, an image processing circuit 320, and a temperature control circuit 330. Furthermore, as described above, the semiconductor package 200 includes the semiconductor chip 210, the package substrate 220, and the Peltier module 230. Industrial equipment (testing equipment or the like), a mirrorless camera, a smartphone, a notebook personal computer, or the like is supposed as the semiconductor device 100.

Various circuits such as a signal processing circuit 215 are provided in the semiconductor chip 210. The signal processing circuit 215 performs various types of processing such as correlated double sampling (CDS) processing and analog to digital (AD) conversion on an analog pixel signal to generate an image signal.

The wire 261-1, which is a power supply line, connects the power supply terminal of the signal processing circuit 215 and the pad 241-1 of the Peltier module 230, and the wire 262-1 connects the pad 241-1 and the inner lead on the package substrate 220. The wire 261-2, which is a ground line, connects the ground terminal of the signal processing circuit 215 and the pad 241-2 of the Peltier module 230, and the wire 262-2 connects the pad 241-2 and the inner lead on the package substrate 220. The power supply circuit 310 supplies power to a circuit (such as the signal processing circuit 215) in the semiconductor chip 210 via these wires (power supply line and ground line).

Furthermore, the wire 263 connects the signal processing circuit 215 and the inner lead on the package substrate 220. The image processing circuit 320 exchanges electric signals such as an image signal and a control signal with the signal processing circuit 215 via the wire 263. The image processing circuit 320 performs various types of processing such as white balance processing and demosaic processing on the image signal, and supplies the image signal to a subsequent circuit.

Furthermore, wires 264-1 and 264-2 connect the Peltier module 230 and the package substrate 220. The temperature control circuit 330 supplies power to the Peltier module 230 via these wires and drives the Peltier module as necessary.

For example, the temperature control circuit 330 acquires a temperature of the semiconductor chip 210, and drives the Peltier module 230 in a case where the temperature exceeds a predetermined upper limit value.

As described above, according to the first embodiment of the present technology, since the power supply line and the ground line connect the semiconductor chip 210 and the package substrate 220 via the pads of the Peltier module 230, the heat return can be suppressed. Therefore, the heat dissipation performance of the semiconductor package 200 can be improved.

### 2. Second Embodiment

In the first embodiment described above, the power supply line and the ground line are connected to the pads on the Peltier module 230. However, a wiring board may be added to the Peltier module 230, and the power supply line and the ground line may be connected to the pads on the wiring board. A semiconductor package 200 according to a second embodiment is different from that of the first embodiment in that a power supply line and a ground line are connected to pads on a wiring board.

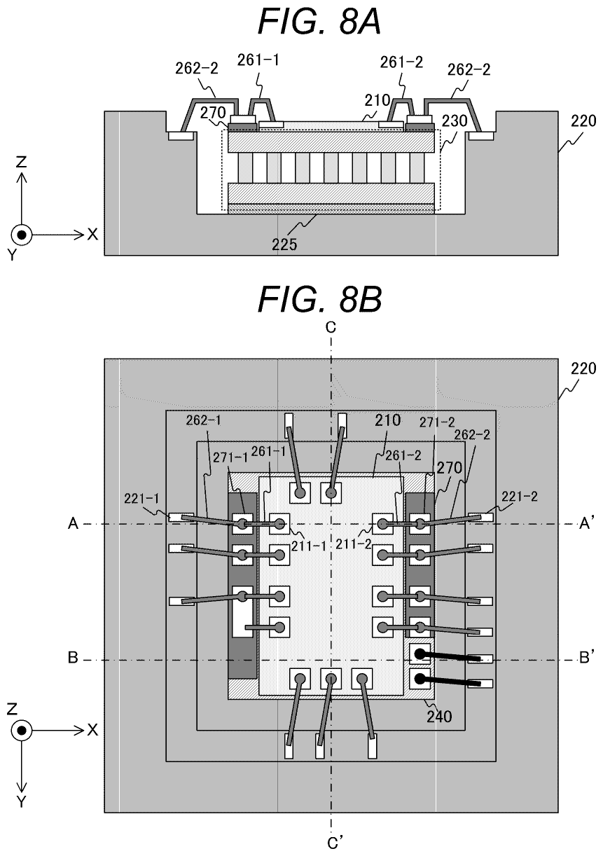

FIG. 8 is an example of a cross-sectional view and a top view illustrating a configuration example of a semiconductor package according to a second embodiment of the present technology. a in the drawing is an example of a cross-sectional view of the semiconductor package 200, and b in the drawing is an example of a top view of the semiconductor package 200. a in the drawing is a cross-sectional view of the semiconductor package 200 cut along a line segment A-A′ of b in the drawing as viewed from the Y-axis direction.

As illustrated in a and b of the drawing, the semiconductor package 200 of the second embodiment is different from that of the first embodiment in that the semiconductor package further includes a predetermined number of wiring board 270.

A semiconductor chip 210 and the wiring board 270 are bonded to an upper surface of a Peltier module 230. A plurality of pads such as 271-1 and 271-2 is disposed on the wiring board 270.

The semiconductor chip 210 is connected to the pad 271-1 of the wiring board 270 by a wire 261-1 (power supply line). Furthermore, the pad 271-1 is connected to a package substrate 220 by a wire 262-1 (power supply line).

Furthermore, the semiconductor chip 210 is connected to the pad 271-2 of the wiring board 270 by a wire 261-2 (ground line). Furthermore, the pad 271-2 is connected to the package substrate 220 by a wire 262-2 (ground line).

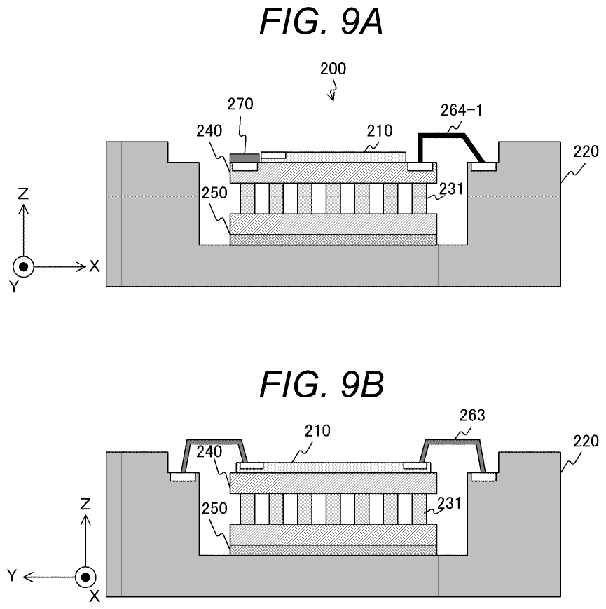

a in FIG. 9 is an example of a cross-sectional view of the semiconductor package taken along a line segment B-B′ of b in FIG. 8 and viewed from the X-axis direction. Similarly to the first embodiment, a Peltier module 230 and the package substrate 220 are electrically connected by a wire 264-1 or the like.

b of FIG. 9 is an example of a cross-sectional view of the semiconductor package taken along a line segment C-C′ of b in FIG. 8 and viewed from the X-axis direction. Similarly to the first embodiment, a semiconductor chip 210 and the package substrate 220 are directly connected by a wire 263 (signal line).

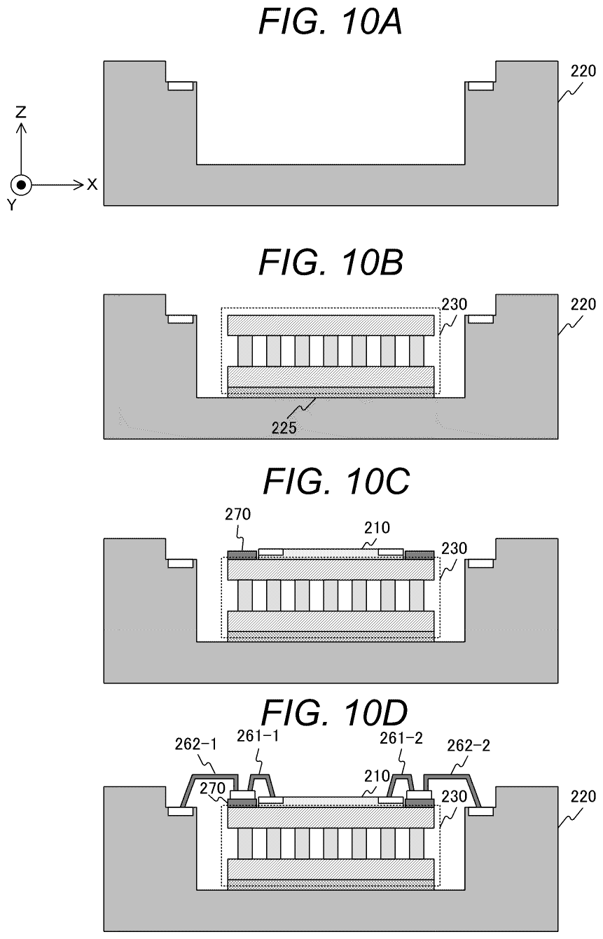

FIG. 10 is a diagram for describing a manufacturing method for the semiconductor package according to the second embodiment of the present technology. First, as illustrated in a of the drawing, the package substrate 220 including the cavity is manufactured.

Next, as exemplified in b of the drawing, the Peltier module 230 is adhered to the bottom surface of the cavity with the adhesive 225 (silver paste or the like).

Then, as illustrated in c of the drawing, the wiring board 270 and the semiconductor chip 210 are mounted on the upper surface of the Peltier module 230.

Subsequently, as illustrated in d of the drawing, the wire 261 connecting the semiconductor chip 210 and the wiring board 270 and the wire 262 connecting the wiring board 270 and the package substrate 220 are wired.

As described above, according to the second embodiment of the present technology, since the power supply line and the ground line connect the semiconductor chip 210 and the package substrate 220 via the pads of the wiring board 270, heat return can be suppressed even in a case where the wiring board 270 is used.

### 3. Third Embodiment

In the second embodiment described above, the wires 264-1 and 264-2 for supplying power to the Peltier module 230 are connected to the pads of the heat absorption side substrate 240, but heat return may occur via these wires. A semiconductor package 200 according to the third embodiment is different from that of the second embodiment in that wires 264-1 and 264-2 are connected to pads of a heat dissipation side substrate 250.

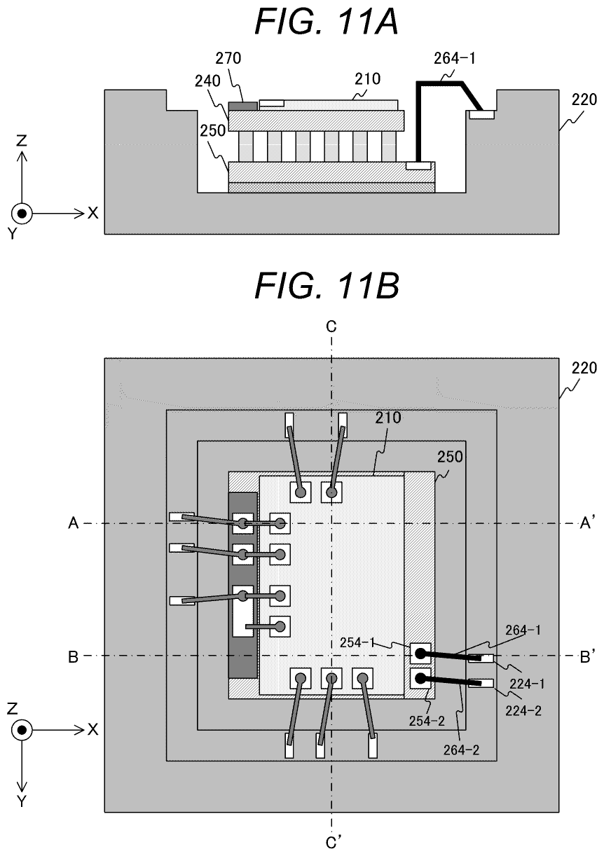

FIG. 11 is an example of a cross-sectional view and a top view illustrating a configuration example of the semiconductor package according to the third embodiment of the present technology. a in the drawing is an example of a cross-sectional view of the semiconductor package 200, and b in the drawing is an example of a top view of the semiconductor package 200. a in the drawing is a cross-sectional view of the semiconductor package 200 cut along a line segment B-B′ of b in the drawing as viewed from the Y-axis direction.

As illustrated in a and b of the drawing, in the third embodiment, an area of the heat dissipation side substrate 250 is larger than that of the heat absorption side substrate 240. Furthermore, pads 244-1 and 244-2 are not disposed on the upper surface of the heat absorption side substrate 240, and instead, pads 254-1 and 254-2 are disposed on the upper surface of the heat dissipation side substrate 250.

Furthermore, the pad 254-1 is used as a + terminal, and is electrically connected to an inner lead 224-1 of a package substrate 220 by a wire 264-1. Furthermore, the pad 254-2 is used as a − terminal, and is electrically connected to an inner lead 224-2 of the package substrate 220 by a wire 264-2. Power is supplied to a Peltier module 230 through these wires.

By connecting the wires 264-1 and 264-2 to the pads of the heat dissipation side substrate 250 farther from the semiconductor chip 210, it is possible to suppress conduction of heat returning via these wires to the semiconductor chip 210. In other words, the influence of the heat return can be suppressed.

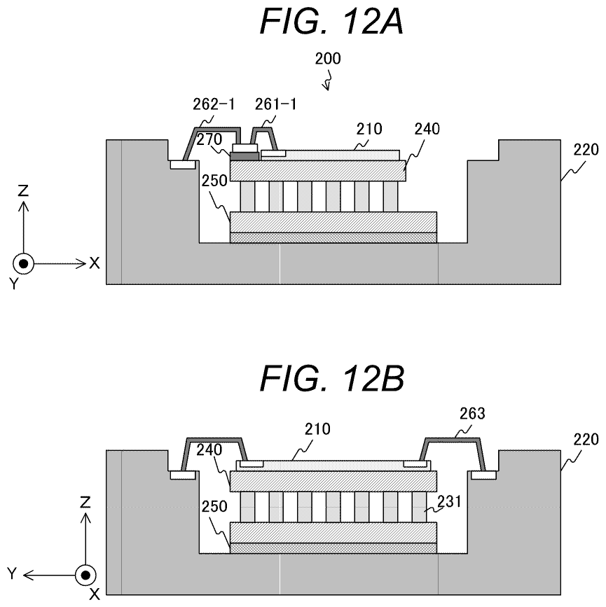

a in FIG. 12 is an example of a cross-sectional view of the semiconductor package 200 taken along a line segment A-A′ of b in FIG. 11 and viewed from the Y-axis direction. Similarly to the second embodiment, the semiconductor chip 210 and the package substrate 220 are connected via the pads of the wiring board 270 by wires 261-1, 262-1, and the like.

b of FIG. 12 is an example of a cross-sectional view of the semiconductor package 200 taken along a line segment C-C′ of b in FIG. 11 and viewed from the X-axis direction. Similarly to the second embodiment, the semiconductor chip 210 and the package substrate 220 are directly connected by a wire 263 (signal line).

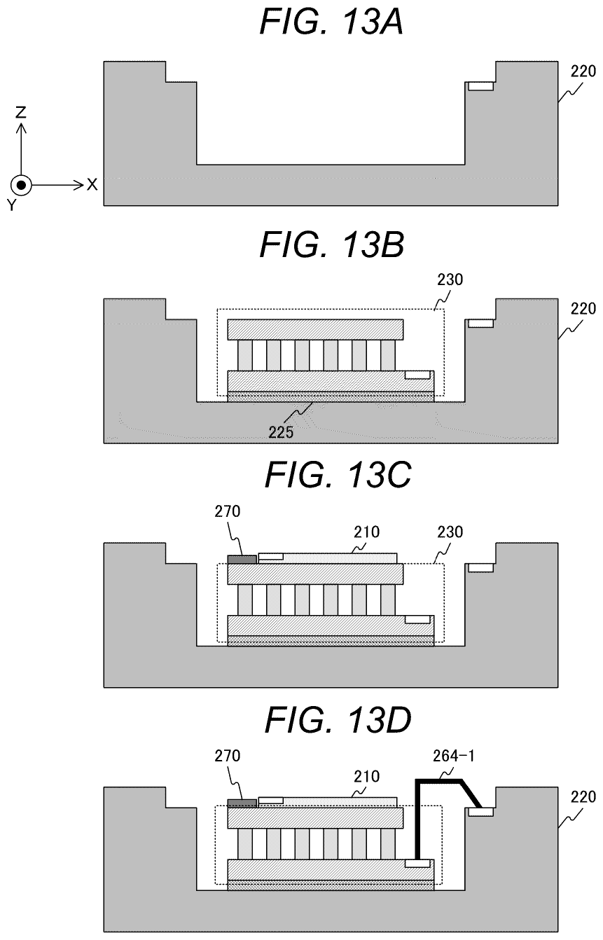

FIG. 13 is a diagram for describing a manufacturing method for the semiconductor package 200 according to the third embodiment of the present technology. As illustrated in a of the drawing, the package substrate 220 including the cavity is manufactured.

Next, as exemplified in b of the drawing, the Peltier module 230 is adhered to the bottom surface of the cavity with the adhesive 225 (silver paste or the like).

Then, as illustrated in c of the drawing, the semiconductor chip 210 and the wiring board 270 are mounted on the upper surface of the Peltier module 230.

Subsequently, as illustrated in D of the drawing, the wire 264-1 or the like connecting the heat dissipation side substrate 250 and the package substrate 220 is wired.

As described above, according to the third embodiment of the present technology, since the wires 264-1 and 264-2 are connected to the pads of the heat dissipation side substrate 250, the influence of heat return through the wires can be suppressed.

### 4. Fourth Embodiment

In the first embodiment described above, the heat absorption side substrate 240 and the heat dissipation side substrate 250 are disposed in the Peltier module 230, but the package substrate 220 can also be used as a substrate on a heat dissipation side instead of the heat dissipation side substrate 250. A semiconductor package 200 according to the fourth embodiment differs from the first embodiment in that the heat dissipation side substrate 250 is reduced.

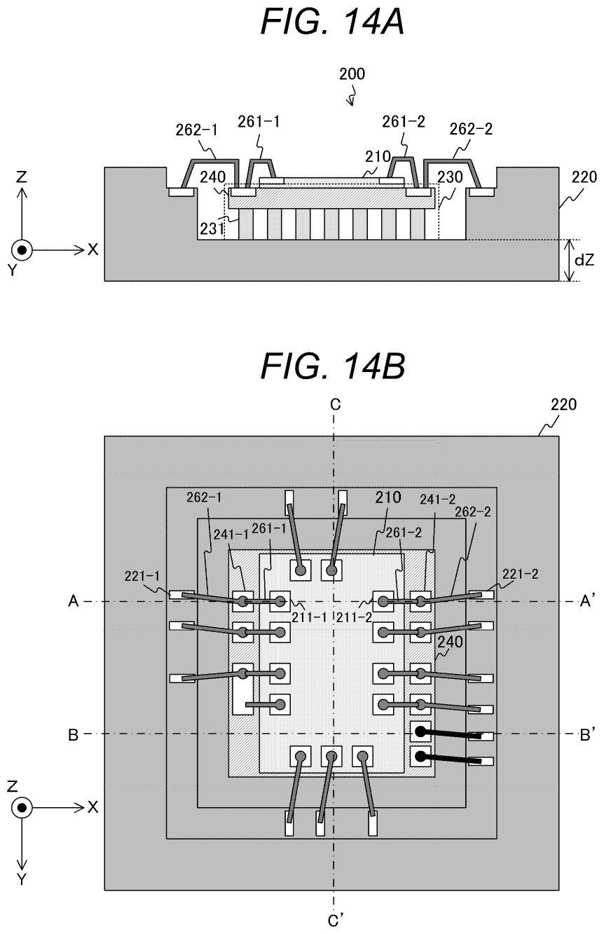

FIG. 14 is an example of a cross-sectional view and a top view illustrating a configuration example of a semiconductor package according to a fourth embodiment of the present technology. a in the drawing is an example of a cross-sectional view of the semiconductor package 200, and b in the drawing is an example of a top view of the semiconductor package 200. a in the drawing is a cross-sectional view of the semiconductor package 200 cut along a line segment A-A′ of b in the drawing as viewed from the Y-axis direction.

As illustrated in a of the drawing, the semiconductor package 200 of the fourth embodiment is different from that of the first embodiment in that a heat dissipation side substrate 250 is not disposed.

A Peltier element 231 is disposed between a heat absorption side substrate 240 and a package substrate 220, and heat is transferred from the heat absorption side substrate 240 to the package substrate 220 by the Peltier element 231. Thus, the package substrate 220 is used as a substrate on the heat dissipation side.

By using the package substrate 220 as the substrate on the heat dissipation side, the heat dissipation side substrate 250 can be reduced. Therefore, the Peltier element can directly transfer heat to the package substrate 220, so that heat dissipation performance can be further improved. Furthermore, heat is dissipated from the lower surface of the package substrate 220, but a thickness dZ from a cavity bottom surface to the heat dissipating surface is preferably thin.

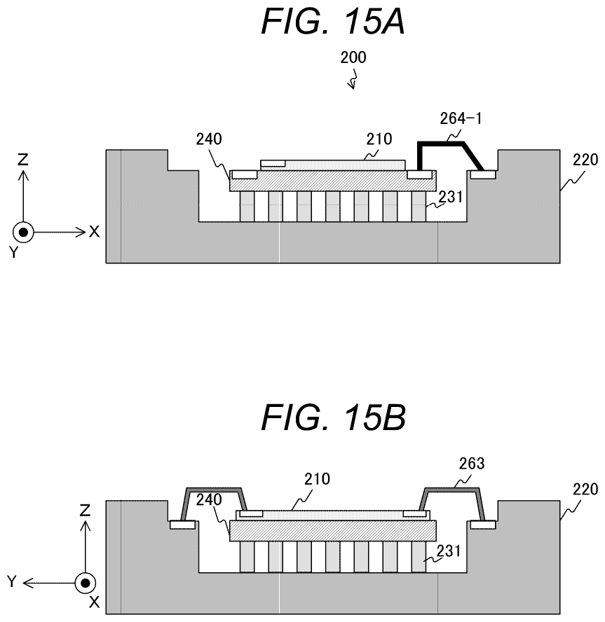

a in FIG. 15 is an example of a cross-sectional view of the semiconductor package taken along a line segment B-B′ of b in FIG. 14 and viewed from the X-axis direction. Similarly to the first embodiment, a Peltier module 230 and the package substrate 220 are electrically connected by a wire 264-1 or the like.

b in FIG. 15 is an example of a cross-sectional view of the semiconductor package taken along a line segment C-C′ of b in FIG. 14 and viewed from the X-axis direction. Similarly to the first embodiment, a semiconductor chip 210 and the package substrate 220 are directly connected by a wire 263 (signal line).

Note that the second embodiment can be applied to the fourth embodiment.

As described above, according to the fourth embodiment of the present technology, since the package substrate 220 is used as the substrate on the heat dissipation side, the heat dissipation side substrate 250 can be reduced, and the heat dissipation performance can be further improved.

### 5. Application Examples to Mobile Body

The technology according to the present disclosure (present technology) can be applied to various kinds of products. For example, the technology according to the present disclosure may also be implemented as a device mounted on any type of mobile body such as an automobile, an electric automobile, a hybrid electric automobile, a motorcycle, a bicycle, a personal mobility, an airplane, a drone, a ship, and a robot.

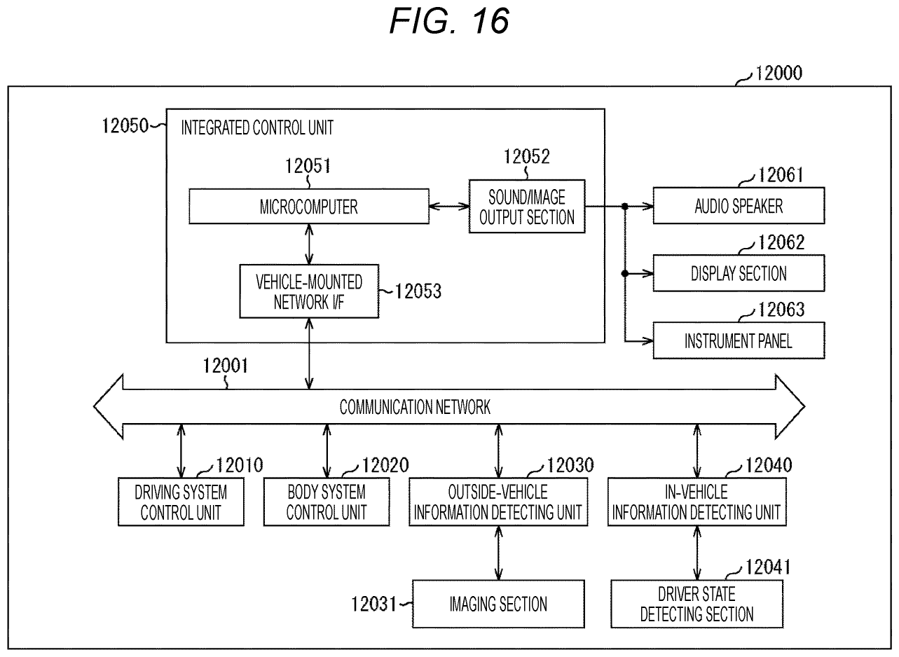

FIG. 16 is a block diagram illustrating an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example illustrated in FIG. 16, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and an in-vehicle network interface (I/F) 12053 are illustrated as functional configurations of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light.

The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 16, an audio speaker 12061, a display section 12062, and an instrument panel 12063 are illustrated as the output device. The display section 12062 may, for example, include at least one of an on-board display and a head-up display.

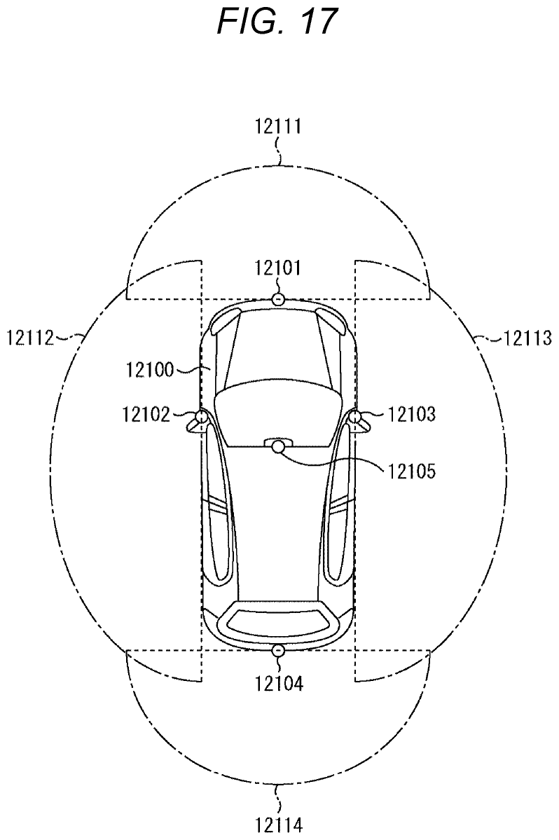

FIG. 17 is a diagram illustrating an example of the installation position of the imaging section 12031.

In FIG. 17, the imaging section 12031 includes imaging sections 12101, 12102, 12103, 12104, and 12105.

The imaging sections 12101, 12102, 12103, 12104, and 12105 are provided at positions, for example, the front nose, the sideview mirrors, the rear bumper, the back door, an upper portion of the windshield in the interior, and the like of the vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly images of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 17 illustrates an example of imaging ranges of the imaging sections 12101 to 12104. An imaging range 12111 represents the imaging range of the imaging section 12101 provided to the front nose.

Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied, for example, to the imaging section 12031 among the constituents described above. Specifically, the semiconductor package 200 in FIG. 1 can be applied to the imaging section 12031. By applying the technology according to the present disclosure to the imaging section 12031, noise or the like can be reduced by the improvement of heat dissipation performance, and a more easily viewable captured image can be obtained, so that driver's fatigue can be reduced.

Note that the embodiments described above indicate examples for embodying the present technology, and the respective matters in the embodiments and the respective matters specifying the invention in the claims have correspondence relationships. Similarly, the respective matters specifying the invention in the claims and the respective matters with the same names in the embodiments of the present technology have correspondence relationships. However, the present technology is not limited to the embodiments, and can be embodied by applying various kinds of modifications to the embodiments without departing from the gist of the present technology.

Note that the effects described herein are merely illustrative and not limiting, and other effects may also be present.

Note that the present technology may also have the following configurations.
(1) A semiconductor package including:
   a semiconductor chip;
   a package substrate;
   a Peltier element that cools a predetermined relay pad and the semiconductor chip;
   a first wire that connects the semiconductor chip and the relay pad; and
   a second wire that connects the relay pad and the package substrate.
(2) The semiconductor package according to (1) described above, further including
   a third wire that connects the package substrate and the semiconductor chip and transmits an electric signal,
   in which power is supplied to the semiconductor chip via the first wire and the second wire.
(3) The semiconductor package according to (1) or (2) described above, in which
   a plurality of the first wires and one of the second wires are connected to one of the relay pads.
(4) The semiconductor package according to any one of (1) to (3) described above, further including:
   a heat absorption side substrate on which the semiconductor chip is mounted; and
   a heat dissipation side substrate bonded to the package substrate with an adhesive,
   in which the Peltier element is disposed between the heat absorption side substrate and the heat dissipation side substrate.
(5) The semiconductor package according to (4) described above, in which
   the relay pad is disposed on the heat absorption side substrate.
(6) The semiconductor package according to (4) described above, further including
   a wiring board bonded to the heat absorption side substrate,
   in which the relay pad is disposed on the wiring board.
(7) The semiconductor package according to any one of (4) to (6) described above, further including
   a fourth wire that connects the heat absorption side substrate and the package substrate,
   in which power is supplied to the Peltier element via the fourth wire.
(8) The semiconductor package according to any one of (4) to (6) described above, further including
   a fourth wire that connects the heat dissipation side substrate and the package substrate,
   in which power is supplied to the Peltier element via the fourth wire.
(9) The semiconductor package according to (1) described above, further including
   a heat absorption side substrate on which the semiconductor chip is mounted,
   in which the Peltier element is disposed between the heat absorption side substrate and the package substrate.
(10) A semiconductor device including:
   a semiconductor chip;
   a package substrate;
   a Peltier element that cools a predetermined relay pad and the semiconductor chip;
   a first wire that connects the semiconductor chip and the relay pad;
   a second wire that connects the relay pad and the package substrate; and
   a power supply circuit that supplies power to the semiconductor chip via the first wire and the second wire.
(11) A manufacturing method for a semiconductor package, the manufacturing method including the steps of:
   disposing, on a package substrate, a Peltier module including a Peltier element that cools a predetermined relay pad and a semiconductor chip;
   mounting the semiconductor chip on the Peltier module; and
   wiring a first wire that connects the semiconductor chip and the relay pad and a second wire that connects the relay pad and the package substrate.

### REFERENCE SIGNS LIST

100 Semiconductor device
200 Semiconductor package
210 Semiconductor chip
211-1, 211-2, 213, 241-1, 241-2, 244-1, 244-2, 254-1, 254-2, 271-1, 271-2 Pad
215 Signal processing circuit
220 Package substrate
221-1, 221-2, 223, 224-1, 224-2 Inner lead
225 Adhesive
230 Peltier module
231 Peltier element
240 Heat absorption side substrate
250 Heat dissipation side substrate
261, 261-1, 261-1a, 261-1b, 261-2, 262, 262-1, 262-2, 263, 264-1, 264-2 Wire
270 Wiring board
300 External circuit
310 Power supply circuit
320 Image processing circuit
330 Temperature control circuit
12031 Imaging section

What is claimed is:

1. A semiconductor package comprising:
a semiconductor chip;
a package substrate;
a Peltier element that cools a predetermined relay pad and the semiconductor chip;
a first wire that connects the semiconductor chip and the relay pad; and
a second wire that connects the relay pad and the package substrate.

2. The semiconductor package according to claim 1, further comprising
a third wire that connects the package substrate and the semiconductor chip and transmits an electric signal,
wherein power is supplied to the semiconductor chip via the first wire and the second wire.

3. The semiconductor package according to claim 1, wherein a plurality of the first wires and one of the second wires are connected to one of the relay pads.

4. The semiconductor package according to claim 1, further comprising:
a heat absorption side substrate on which the semiconductor chip is mounted; and
a heat dissipation side substrate bonded to the package substrate with an adhesive,
wherein the Peltier element is disposed between the heat absorption side substrate and the heat dissipation side substrate.

5. The semiconductor package according to claim 4, wherein
the relay pad is disposed on the heat absorption side substrate.

6. The semiconductor package according to claim 4, further comprising
a wiring board bonded to the heat absorption side substrate,
wherein the relay pad is disposed on the wiring board.

7. The semiconductor package according to claim 4, further comprising
a fourth wire that connects the heat absorption side substrate and the package substrate,
wherein power is supplied to the Peltier element via the fourth wire.

8. The semiconductor package according to claim 4, further comprising
a fourth wire that connects the heat dissipation side substrate and the package substrate,
wherein power is supplied to the Peltier element via the fourth wire.

9. The semiconductor package according to claim 1, further comprising
a heat absorption side substrate on which the semiconductor chip is mounted,
wherein the Peltier element is disposed between the heat absorption side substrate and the package substrate.

10. A semiconductor device comprising:
a semiconductor chip;
a package substrate;
a Peltier element that cools a predetermined relay pad and the semiconductor chip;
a first wire that connects the semiconductor chip and the relay pad;
a second wire that connects the relay pad and the package substrate; and
a power supply circuit that supplies power to the semiconductor chip via the first wire and the second wire.

11. A manufacturing method for a semiconductor package, the manufacturing method comprising the steps of:
disposing, on a package substrate, a Peltier module including a Peltier element that cools a predetermined relay pad and a semiconductor chip;
mounting the semiconductor chip on the Peltier module; and
wiring a first wire that connects the semiconductor chip and the relay pad and a second wire that connects the relay pad and the package substrate.
